(19) United States
(12) Patent Application Publication
(10) Pub. No.: US 2024/0349575 A1
(43) Pub. Date: Oct. 17, 2024

(54) COVER PLATE, DISPLAY MODULE, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Xi Zhu, Beijing (CN); Chen Li, Beijing (CN); Qiang Tang, Beijing (CN); Xu Fan, Beijing (CN); Lei Zhang, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/694,170

(22) PCT Filed: Jul. 31, 2023
(86) PCT No.: PCT/CN2023/110363

§ 371 Date: Mar. 21, 2024

(30) Foreign Application Priority Data
Sep. 14, 2022 (CN) 202211114870.2

(51) Int. Cl. H10K 59/80; H10K 59/131

(52) U.S. Cl. CPC H10K 59/872; H10K 59/1315; H10K 59/8792

(57) ABSTRACT

Provided are a cover plate, a display module, and a display device. The cover plate includes: a cover plate base (10) and an anti-fingerprint film layer (11) disposed on a side of the cover plate base (10); and an electrostatic transfer layer (20) disposed between the cover plate base (10) and the anti-fingerprint film layer (11) or disposed on a side of the cover plate base (10) facing away from the anti-fingerprint film layer (11).

### CROSS-REFERENCE TO RELATED APPLICATION

The present disclosure claims priority to Chinese Patent application No. 202211114870.2 submitted to China National Intellectual Property Administration on Sep. 14, 2022, entitled “COVER PLATE, DISPLAY MODULE, AND DISPLAY DEVICE”, which is incorporated herein in its entirety by reference.

### TECHNICAL FIELD

The present disclosure relates to the field of display technology, in particular to a cover plate, a display module, and a display device.

### BACKGROUND

With the development of display technology, a display device is increasingly widely used. In general, the display device is composed of a display panel and a cover plate located on a surface of the display panel on a display direction side. The cover plate not only protects the display panel but also optimizes the appearance of the display device.

### SUMMARY

A first aspect of the present disclosure provides a cover plate, including:
a cover plate base and an anti-fingerprint film layer disposed on a side of the cover plate base; and
an electrostatic transfer layer disposed between the cover plate base and the anti-fingerprint film layer or disposed on a side of the cover plate base facing away from the anti-fingerprint film layer,
the electrostatic transfer layer is configured to transfer static electricity generated by the cover plate.

In some embodiments, the cover plate further includes:
a substrate layer doped with conductive particles;
the electrostatic transfer layer is disposed between the cover plate base and the anti-fingerprint film layer, and the substrate layer is located between the electrostatic transfer layer and the anti-fingerprint film layer; or
the electrostatic transfer layer is disposed on the side of the cover plate base facing away from the anti-fingerprint film layer, and the substrate layer is located between the cover plate base and the anti-fingerprint film layer.

In some embodiments, the cover plate includes a central region and an edge region surrounding the central region, and the cover plate further includes:
a light shielding layer located in the edge region;
the electrostatic transfer layer is disposed between the cover plate base and the anti-fingerprint film layer, and the light shielding layer is located on a side of the cover plate base facing away from the electrostatic transfer layer; or
the electrostatic transfer layer is disposed on the side of the cover plate base facing away from the anti-fingerprint film layer, and the light shielding layer is located on a side of the electrostatic transfer layer facing away from the cover plate base.

In some embodiments, the cover plate further includes:
an electrostatic conduction portion connected to the electrostatic transfer layer and located on at least one side face of the cover plate base, the side face connecting a surface on a side of the cover plate base close to the anti-fingerprint film layer and a surface on the side of the cover plate base facing away from the anti-fingerprint film layer.

In some embodiments, the electrostatic conduction portion and the electrostatic transfer layer are made of a same material and have an integrated structure.

In some embodiments, a material of the electrostatic transfer layer comprises at least one of: ITO, AZO, ZnO, Al₂O₃, Nb₂O₅, NiO₂, TiO₂, SnO₂, In₂O₃, Ga₂O₃, MgZnO, GalnO, and InGaZnO.

In some embodiments, the electrostatic transfer layer has a transmittance greater than or equal to 98% for light with a wavelength of 550 nm.

In some embodiments, the electrostatic transfer layer has a thickness greater than or equal to 1 nm, and less than or equal to 15 nm.

In some embodiments, a resistance value of a surface of the electrostatic transfer layer close to the anti-fingerprint film layer is greater than or equal to 10⁸Ω and less than or equal to 10¹²Ω; and/or

a surface roughness on a side of the electrostatic transfer layer close to the anti-fingerprint film layer is less than 0.5 nm.

In some embodiments, the anti-fingerprint film layer comprises at least one of: fluorine chains, non-fluorine groups and terminal groups.

In some embodiments, a relative molecular weight of the fluorine chains is greater than or equal to 1000, and less than or equal to 4500.

In some embodiments, a number of terminal groups is greater than or equal to 2.

In some embodiments, the cover plate base includes a plurality of sub-film layers stacked; the plurality of sub-film layers are all made of a flexible material.

A second aspect of the present disclosure provides a display module, including:
a display panel; and
the cover plate described in the first aspect disposed on a display side of the display panel,
the anti-fingerprint film layer is disposed on a side of the cover plate base facing away from the display panel.

In some embodiments, the cover plate includes an electrostatic conduction portion connected to the electrostatic transfer layer and located on at least one side face of the cover plate base, the side face connecting a surface on a side of the cover plate base close to the anti-fingerprint film layer and a surface on the side of the cover plate base facing away from the anti-fingerprint film layer, the display module further includes:
a middle frame disposed along a side face of the cover plate and enclosing the cover plate and the display panel; and
a middle frame adhesive layer located between the middle frame and the side face of the cover plate;
the electrostatic conduction portion is connected to the middle frame through the middle frame adhesive layer.

In some embodiments, a resistivity of the middle frame adhesive layer is less than or equal to the resistivity of the electrostatic conduction portion, and the resistivity of the middle frame is less than or equal to the resistivity of the middle frame adhesive layer.

A third aspect of the present disclosure provides a display device including the display module according to the second aspect of the present disclosure.

### BRIEF DESCRIPTION OF THE DRAWINGS

In order to describe technical solutions in embodiments of the present disclosure or the related art more clearly, the accompanying drawings which are used in the description of the embodiments or the related art will be briefly introduced. Apparently, the accompanying drawings in the following description illustrate some embodiments of the present disclosure, based on these accompanying drawings, those skilled in the art may obtain other accompanying drawings without paying any creative effort.

FIG. 1 is a schematic plan diagram illustrating a cover plate according to an embodiment of the present disclosure;

FIG. 2 is a schematic structural diagram of a cover plate according to an embodiment of the present disclosure;

FIG. 3 is a schematic structural diagram of another cover plate according to an embodiment of the present disclosure;

FIG. 4 is a schematic diagram illustrating a molecular structure of a anti-fingerprint film layer of a cover plate according to an embodiment of the present disclosure;

FIG. 5 is a schematic structural diagram of a cover plate including a substrate layer according to an embodiment of the present disclosure;

FIG. 6 is a schematic structural diagram of another cover plate including a substrate layer according to an embodiment of the present disclosure;

FIG. 7 is a schematic structural diagram of a cover plate including a light shielding layer according to an embodiment of the present disclosure;

FIG. 8 is a schematic structural diagram of another cover plate including a light shielding layer according to an embodiment of the present disclosure;

FIG. 9 is a schematic structural diagram of a cover plate including an electrostatic conduction portion according to an embodiment of the present disclosure;

FIG. 10 is a schematic structural diagram of a cover plate including multiple sub-film layers according to an embodiment of the present disclosure;

FIG. 11 is a schematic structural diagram of another cover plate including multiple sub-film layers according to an embodiment of the present disclosure; and

FIG. 12 is a schematic structural diagram of a display module according to an embodiment of the present disclosure.

### DETAILED DESCRIPTION

To make the objects, technical solutions and advantages of embodiments of the present disclosure clearer, the technical solutions in some embodiments of the present disclosure will be clearly and thoroughly described below with reference to the accompanying drawings. Apparently, the described embodiments are only some of the embodiments of the present disclosure, rather than all of the embodiments. Based on the embodiments provided by this disclosure, all other embodiments obtained by those skilled in the art fall within the scope of protection of this disclosure.

In a display device in the related art, an anti-fingerprint film layer is usually disposed on a cover plate so as to improve the strength of a screen of the display device. The material of the anti-fingerprint film layer is mainly a high molecular fluoride (for example, perfluoropolyether), while a friction test is performed on the anti-fingerprint film layer during the manufacturing of the display device, so as to ensure the reliability of the anti-fingerprint film layer.

During the friction test, electrostatic charges are generated on the surface of the anti-fingerprint film layer due to friction, and these electrostatic charges may accumulate on the surface of the anti-fingerprint film layer. As a result, effective components (fluorine chains) of the anti-fingerprint film layer are entangled and agglomerated under the action of the charges, and the wear resistance and durability of the anti-fingerprint film layer are reduced. Moreover, these electrostatic charges are also transferred to the surface of the cover plate and continuously accumulate on the surface of the cover plate, resulting in an electrostatic discharge (ESD) phenomenon. When the electrostatic discharge phenomenon occurs, the display module of the display device is liable to be broken down or displays abnormally.

In view of this, the present disclosure provides a cover plate, a display module, and a display device. The cover plate includes a cover plate base and an anti-fingerprint film layer disposed on a side of the cover plate base. The cover plate further includes an electrostatic transfer layer. The electrostatic transfer layer is disposed between the cover plate base and the anti-fingerprint film layer, and/or disposed on a side of the cover plate base facing away from the anti-fingerprint film layer. The electrostatic transfer layer is configured to transfer static electricity generated by the cover plate. After electrostatic charges are generated on the anti-fingerprint film layer due to friction, the electrostatic charges are transferred to the electrostatic transfer layer and discharged through the electrostatic transfer layer. In this way, the accumulation of the electrostatic charges on the anti-fingerprint film layer or the cover plate base can be prevented, thereby improving the durability of the anti-fingerprint film layer. Moreover, display abnormality of the display module caused by the breakdown of the display module due to the electrostatic release can also be avoided.

To make the above objects, features and advantages of the present disclosure to be clearer and understood, a cover plate, a display module, and a display device according to the present disclosure will now be further described in detail with reference to the accompanying drawings and detailed description.

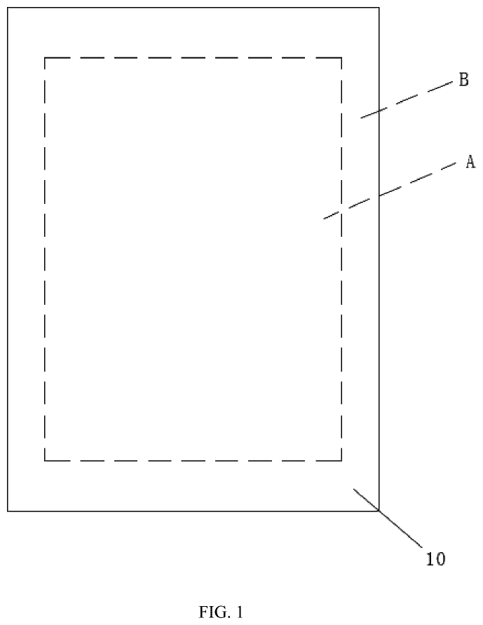

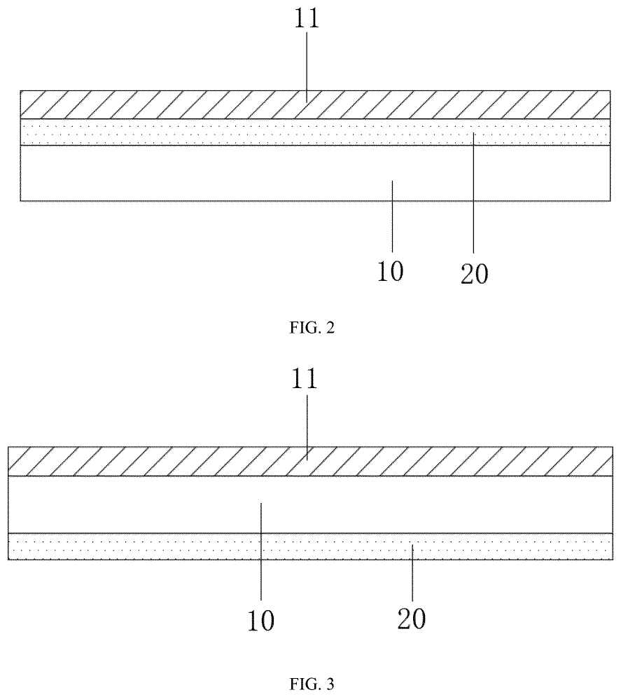

FIG. 1 is a schematic plan diagram of a cover plate according to the present disclosure. FIG. 2 is a schematic structural diagram of a cover plate according to the present disclosure. Referring to FIG. 1 and FIG. 2, the cover plate includes a cover plate base 10, an anti-fingerprint film layer 11 disposed on a side of the cover plate base 10, and an electrostatic transfer layer 20.

Specifically, the cover plate base 10 may include a rigid base or a flexible base. Exemplarily, the cover plate base 10 may be a rigid base such as glass, polycarbonate (PC) or polymethyl methacrylate (PMMA) when a product has a certain rigidity requirement. The cover plate base 10 may be a flexible base such as polyethylene glycol terephthalate (PET) or colorless polyimide (CPI) when the product is required to be foldable, bendable, or rollable.

The anti-fingerprint film layer 11 is disposed on a side of the cover plate base 10, and the material of the anti-fingerprint film layer 11 mainly includes a high molecular fluoride such as perfluoropolyether. By disposing the anti-fingerprint film layer 11, a surface of the cover plate has a certain resistance to fingerprints and scratches.

The electrostatic transfer layer 20 is disposed between the cover plate base 10 and the anti-fingerprint film layer 11, or disposed on a side of the cover plate base 10 facing away from the anti-fingerprint film layer 11. That is, the cover plate base 10 has a first side and a second side. The first side is a side where the anti-fingerprint film layer 11 is located. As shown in FIG. 2, the electrostatic transfer layer 20 may be disposed only on the first side, and located between the cover plate base 10 and the anti-fingerprint film layer 11. As shown in FIG. 3, the electrostatic transfer layer 20 may be disposed only on the second side. In an alternative embodiment, the electrostatic transfer layer 20 may also be disposed on both the first side and the second side of the cover plate base 10. However, in general, a single-sided electrostatic transfer layer 20 is sufficient to meet the need to transfer electrostatic charges. Therefore, in order to reduce the overall thickness of the cover plate, generally only the single-sided electrostatic transfer layer 20 is disposed.

The electrostatic transfer layer 20 is configured to transfer static electricity generated by the cover plate. Therefore, the electrostatic transfer layer 20 needs to adopt a material having a conductive ability, and the electrostatic transfer layer 20 is grounded, so that the electrostatic charges may be transferred and discharged through the electrostatic transfer layer 20, thereby avoiding the accumulation of the electrostatic charges on the surface of the anti-fingerprint film layer 11 (namely, a side of the anti-fingerprint film layer 11 facing away from the cover plate base 10) or the surface of the cover plate base 10 (namely, a side of the cover plate base 10 facing the anti-fingerprint film layer 11).

Exemplarily, the material of the electrostatic transfer layer 20 may include one or more of ITO, AZO, ZnO, Al₂O₃, Nb₂O₅, NiO₂, TiO₂, SnO₂, In₂O₃, Ga₂O₃, MgZnO, GalnO, and InGaZnO as a main component, and some non-conductive materials may also be doped with respect to some materials with a strong conductivity.

Moreover, the addition of the electrostatic transfer layer 20 tends to affect the light transmittance of the cover plate, thus there is a certain requirement for the transmittance of the electrostatic transfer layer 20 in addition to the material of the electrostatic transfer layer 20. Exemplarily, the electrostatic transfer layer 20 has a transmittance greater than or equal to 98% for light with a wavelength of 550 nm. In this way, as compared with a cover plate without the electrostatic transfer layer 20, the cover plate provided with the electrostatic transfer layer 20 can control the transmittance for light with a wavelength of 550 nm to be reduced a value within 1%. Therefore, the addition of the electrostatic transfer layer 20 will not affect the overall display brightness of the display module.

Further, the electrostatic transfer layer 20 has a thickness greater than or equal to 1 nm and less than or equal to 15 nm. Exemplarily, the thickness of the electrostatic transfer layer 20 may be 1 nm, 2 nm, 3 nm, 4 nm, 5 nm, 8 nm, 10 nm, 12 nm, 15 nm, or the like. In this way, the electrostatic transfer layer 20 has an ability to transfer electrostatic charges without affecting the light transmission of the cover plate due to the excessive thickness of the electrostatic transfer layer 20. In practical applications, the thickness of the electrostatic transfer layer 20 is preferably in the range of 1 nm to 5 nm so as to reduce the overall thickness of the cover plate.

Further, in order to ensure the transfer rate of the electrostatic charges, a resistance value of the surface of the electrostatic transfer layer 20 (namely, a surface on a side of the electrostatic transfer layer 20 close to the anti-fingerprint film layer 11) needs to meet a certain requirement. Specifically, the resistance value of the surface of the electrostatic transfer layer 20 close to the anti-fingerprint film layer 11 may be greater than or equal to 10⁸Ω and less than or equal to 10¹²Ω. Exemplarily, the resistance value of the surface of the electrostatic transfer layer 20 close to the anti-fingerprint film layer 11 may be 10⁸Ω, 10⁹Ω, 10¹⁰Ω, 10¹¹Ω, 10¹²Ω, or the like. In this way, the resistivity of the surface on the side of the electrostatic transfer layer 20 close to the anti-fingerprint film layer 11 can be reduced, thereby preventing the electrostatic charges from accumulating on the surface on the side of the electrostatic transfer layer 20 close to the anti-fingerprint film layer 11, improving the anti-static ability of the electrostatic transfer layer, and allowing the electrostatic charges to be better transferred and discharged from the electrostatic transfer layer. In practical applications, the resistance value of the surface of the electrostatic transfer layer 20 close to the anti-fingerprint film layer 11 is preferably between 10⁹Ω and 8*10⁹Ω.

Furthermore, the surface roughness of the side of the electrostatic transfer layer 20 close to the anti-fingerprint film layer 11 is less than 0.5 nm, so as to ensure that the electrostatic transfer layer 20 has better wear resistance, thereby improving the durability of the electrostatic transfer layer 20. In addition, the resistance variation of the electrostatic transfer layer 20 monitored under an environmental of high temperature and high humidity is less than 5%, whereby the electrostatic transfer layer maintains a better anti-static ability in a high temperature and high humidity environment.

In the cover plate provided by the present disclosure, after electrostatic charges are generated by the anti-fingerprint film layer 11 due to the friction, these electrostatic charges may be transferred to the electrostatic transfer layer 20 and discharged through the electrostatic transfer layer 20, so that the electrostatic charges do not accumulate on the anti-fingerprint film layer 11, thereby effectively avoiding fluorine chains in the anti-fingerprint film layer 11 being entangled and agglomerated under the action of the charges, improving the durability of the anti-fingerprint film layer 11. Moreover, it can also avoid display abnormality caused by the breakdown of the display module due to the accumulation of the electrostatic charges on the cover plate base 10, and the service life of the display module is prolonged.

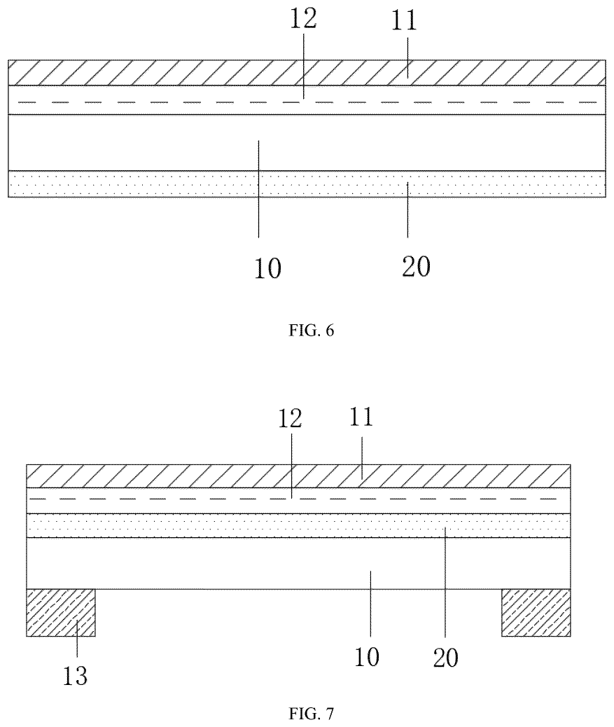

In an alternative embodiment, referring to FIG. 5 and FIG. 6, the present disclosure provides a cover plate that further includes a substrate layer 12. The substrate layer 12 is disposed between the cover plate base 10 and the anti-fingerprint film layer 11. The substrate layer 12 is mainly configured to protect the cover plate base 10, and also configured to connect the anti-fingerprint film layer 11 to the cover plate base 10.

Specifically, the position of the substrate layer 12 varies depending on the position at which the electrostatic transfer layer 20 is disposed. As shown in FIG. 5, when the electrostatic transfer layer 20 is disposed between the cover plate base 10 and the anti-fingerprint film layer 11, the substrate layer 12 is located between the electrostatic transfer layer 20 and the anti-fingerprint film layer 11. As shown in FIG. 6, when the electrostatic transfer layer 20 is disposed on a side of the cover plate base 10 facing away from the anti-fingerprint film layer 11, the substrate layer 12 is located between the cover plate base 10 and the anti-fingerprint film layer 11.

Further, the material of the substrate layer 12 includes an inorganic material, such as SiO₂. In the present disclosure, in order to increase the transfer rate of electrostatic charges in the substrate layer 12, the material of the substrate layer 12 may also be doped with Al₂O₃ at a percentage composition of 1% to 10%. A certain amount of Al₂O₃ may increase the conductivity of the substrate layer 12, so that the substrate layer 12 may better transfer the electrostatic charges. Preferably, the percentage composition of Al₂O₃ may be 5%˜8%. Also, the substrate layer 12 is doped with conductive particles, such as electrons/holes, for further improving the transfer rate of the electrostatic charges.

Further, the substrate layer 12 has a thickness greater than or equal to 2 nm and less than or equal to 60 nm. Exemplarily, the thickness of the substrate layer 12 may be 2 nm, 5 nm, 8 nm, 15 nm, 20 nm, 30 nm, 60 nm, or the like. In practical applications, in order to ensure that the thickness of the cover plate is within a certain range and that the electrostatic charges may pass through the substrate layer 12 more quickly, the thickness of the substrate layer 12 is preferably in the range of 5 nm to 20 nm, thereby further preventing the accumulation of the electrostatic charges on the anti-fingerprint film layer 11.

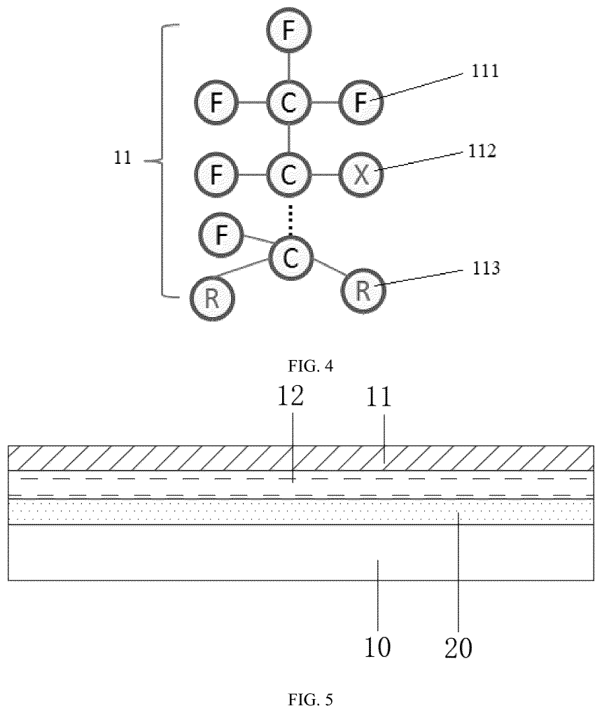

In an alternative embodiment, referring to FIG. 4, the present disclosure provides a cover plate, in which the anti-fingerprint film layer 11 includes at least one of fluorine chains 111, non-fluorine groups 112 and terminal groups 113.

Specifically, in order to ensure that the anti-fingerprint film layer 11 has the anti-static ability, to prevent the anti-fingerprint film layer 11 from failure due to the accumulation of the electrostatic charges, in the present disclosure, a relative molecular weight of all the fluorine chains 111 contained in the anti-fingerprint film layer 11 is greater than or equal to 1000, and less than or equal to 4500. The relative molecular weight of the fluorine chains 111 contained in the anti-fingerprint film layer 11 in the present disclosure is smaller than that of the anti-fingerprint film layer 11 in the related art. Therefore, when the fluorine chains are contacted with the electrostatic charges, the entanglement and agglomeration of the fluorine chains will be reduced, thereby improving the anti-static ability of the anti-fingerprint film layer 11.

Further, in order to further increase the anti-static ability of the anti-fingerprint film layer 11, the anti-fingerprint film layer 11 of the present disclosure also includes non-fluorine groups 112 with weak bond energy. Since the electrostatic charges generated by the anti-fingerprint film layer 11 due to friction are negative charges, the non-fluorine groups 112 are positively charged groups such as amino groups. In this way, the non-fluorine groups 112 may neutralize the electrostatic charges, thereby preventing the electrostatic charges from accumulating on the surface of the anti-fingerprint film layer 11.

Further, the anti-fingerprint film layer 11 includes terminal groups 113. The terminal groups 113 refer to groups for connecting the anti-fingerprint film layer 11 to the substrate layer 12 or the cover plate base 10. In the related art, the number of the terminal groups 113 included in the anti-fingerprint film layer 11 is generally one. In the present disclosure, the number of the terminal groups 113 is greater than or equal to 2. That is, the number of the terminal groups 113 may be 2, 3, 4, or the like. The increased number of the terminal groups 113 advantageously increases the adhesion of the anti-fingerprint film layer 11, so that the anti-fingerprint film layer 11 may be better attached to the substrate layer 12 or the cover plate base 10.

Further, the anti-fingerprint film layer 11 has a thickness less than or equal to 15 nm. Exemplarily, the thickness of the anti-fingerprint film layer 11 may be 1 nm, 3 nm, 5 nm, 8 nm, 10 nm, 15 nm, or the like. Those skilled in the art may determine the thickness of the anti-fingerprint film layer 11 according to actual requirements of a product.

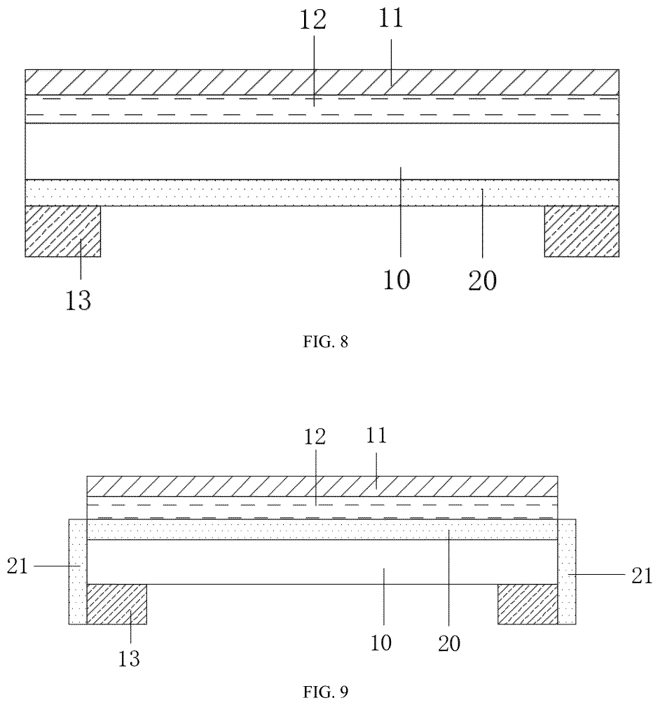

In an alternative embodiment, referring to FIG. 1, FIG. 7 and FIG. 8, the present disclosure provides a cover plate including a central region A and an edge region B surrounding the central region A, and the cover plate further includes a light shielding layer 13 located in the edge region B.

Specifically, in the display module, the central region A of the cover plate corresponds to a display region of a display panel 30, namely a light emitting region of the display panel 30, and the edge region B of the cover plate is a non-light emitting region surrounding the light emitting region. The light shielding layer 13 is located in the edge region B, and the light shielding layer 13 is disposed so that light can only be emitted out of the display module from the light emitting region of the display panel 30, thereby improving the display brightness of the display module.

Further, the position of the light shielding layer 13 relative to the cover plate base 10 needs to be determined according to the position of the electrostatic transfer layer 20. As shown in FIG. 7, when the electrostatic transfer layer 20 is disposed between the cover plate base 10 and the anti-fingerprint film layer 11, the light shielding layer 13 is located on a side of the cover plate base 10 facing away from the electrostatic transfer layer 20, that is, the light shielding layer 13 is in contact with the cover plate base 10. As shown in FIG. 8, when the electrostatic transfer layer 20 is disposed on the side of the cover plate base 10 facing away from the anti-fingerprint film layer 11, the light shielding layer 13 is located on a side of the electrostatic transfer layer 20 facing away from the cover plate base 10, that is, the light shielding layer 13 is in contact with the electrostatic transfer layer 20.

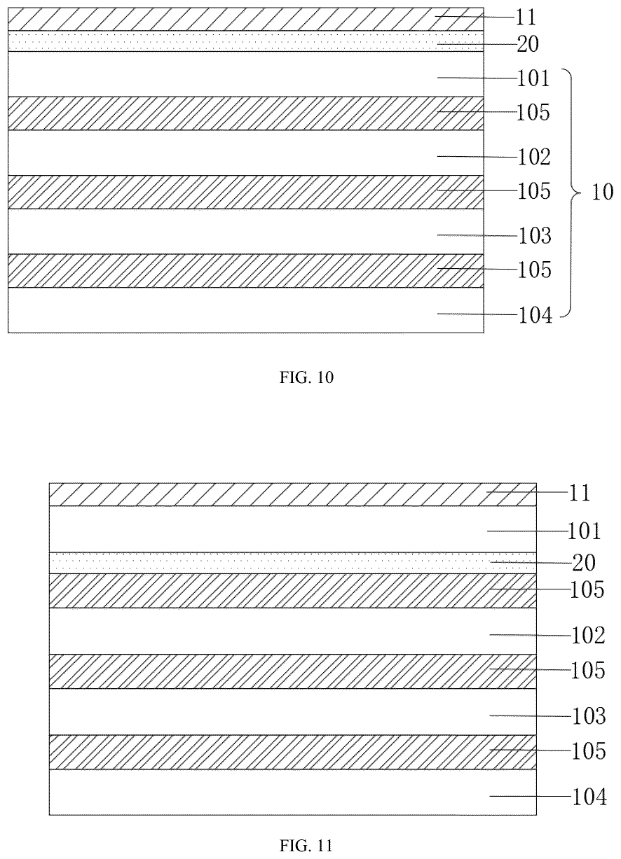

In an alternative embodiment, referring to FIG. 10 and FIG. 11, the present disclosure provides a cover plate. In the cover plate, the cover plate base 10 is a flexible base, and the cover plate base 10 includes a plurality of sub-film layers. Each sub-film layer is made of a flexible material.

Specifically, the cover plate base 10 may be composed of a plurality of flexible sub-film layers stacked when the product is required to be foldable or bendable. Exemplarily, as shown in FIG. 10, the cover plate base 10 may include a first sub-film layer 101, a second sub-film layer 102, a third sub-film layer 103, and a fourth sub-film layer 104 stacked from top to bottom. The anti-fingerprint film layer 11 is disposed on a side of the first sub-film layer 101 facing away from the second sub-film layer 102. The first sub-film layer 101, the second sub-film layer 102, the third sub-film layer 103, and the fourth sub-film layer 104 are connected via an adhesive layer 105. The material of the adhesive layer 105 may include an optical clear adhesive (OCA).

Further, in this embodiment, as shown in FIG. 10, the electrostatic transfer layer 20 may be disposed between the anti-fingerprint film layer 11 and the first sub-film layer 101. Alternatively, as shown in FIG. 11, the electrostatic transfer layer 20 may be disposed on a side of the first sub-film layer 101 facing away from the anti-fingerprint film layer 11. The electrostatic charges generated on the anti-fingerprint film layer 11 due to friction may be transferred and discharged by the electrostatic transfer layer 20, thereby avoiding the accumulation of the electrostatic charges on the anti-fingerprint film layer 11 or the first sub-film layer 101.

Further, the material of the first sub-film layer 101 may include polyethylene terephthalate (PET), colorless polyimide (CPI), and the like. The materials of the second sub-film layer 102, the third sub-film layer 103 and the fourth sub-film layer 104 may include polyethylene terephthalate (PET), thermoplastic urethane (TPU), ultra-thin glass (UTG), ultra-fine grain (UFG), colorless polyimide (CPI), and the like.

Further, in an alternative embodiment, the anti-fingerprint film layer 11 may adopt polymer materials. That is, the anti-fingerprint film layer 11 may be combined with the electrostatic transfer layer 20, so that the anti-fingerprint film layer 11 has an ability of transferring and discharging electrostatic charges while having the anti-fingerprint ability. After the anti-fingerprint film layer 11 and the electrostatic transfer layer 20 are combined, the hardness of the anti-fingerprint film layer 11 is required to be greater than or equal to 2H, the friction resistance is required to be greater than or equal to 1500 steel wool tests, the bending radius is required to be R1.0, and the number of bending is required to be greater than or equal to 200,000. Also, the resistance value of a surface of the anti-fingerprint film layer 11 away from the first sub-film layer 101 is required to be greater than or equal to 10⁸Ω and less than or equal to 10¹²Ω.

When the electrostatic transfer layer 20 is located on the side of the first sub-film layer 101 facing away from the anti-fingerprint film layer 11, the electrostatic transfer layer 20 is required to avoid a phenomenon of breaking and peeling off when the bending radius is R1.0 and the number of bending is greater than or equal to 200,000, and the resistance value variation of a surface of the electrostatic transfer layer 20 away from the first sub-film layer 101 before and after the bending test is required to be less than or equal to 5%.

In an alternative embodiment, referring to FIG. 9, the present disclosure provides a cover plate that further includes an electrostatic conduction portion 21. The electrostatic conduction portion 21 is connected to the electrostatic transfer layer 20, and the electrostatic transfer layer 20 is located on at least one side face of the cover plate base 10.

Specifically, the cover plate base 10 includes a first surface and a second surface. The first surface is a surface on a side of the cover plate base 10 close to the anti-fingerprint film layer 11, and the second surface is a surface on a side of the cover plate base 10 facing away from the anti-fingerprint film layer 11. The side face of the cover plate base 10 is a face connecting the first surface and the second surface. In this embodiment, the cover plate base 10 includes four side faces, and the electrostatic conduction portion 21 covers the four side faces of the cover plate base 10. After the electrostatic charges are transferred to the electrostatic transfer layer 20, the electrostatic charges are transferred to the electrostatic conduction portion 21, and finally discharged through the electrostatic conduction portion 21, thereby preventing the electrostatic charges from entering the display module and avoiding the situation of green screen.

Further, the electrostatic conduction portion 21 and the electrostatic transfer layer 20 are made of the same material, and the electrostatic conduction portion 21 and the electrostatic transfer layer 20 have an integrated structure. That is, the electrostatic conduction portion 21 may be formed during the process of forming the electrostatic transfer layer 20.

Further, the electrostatic conduction portion 21 may extend to a side face of the light shielding layer 13 and cover the side face of the light shielding layer 13.

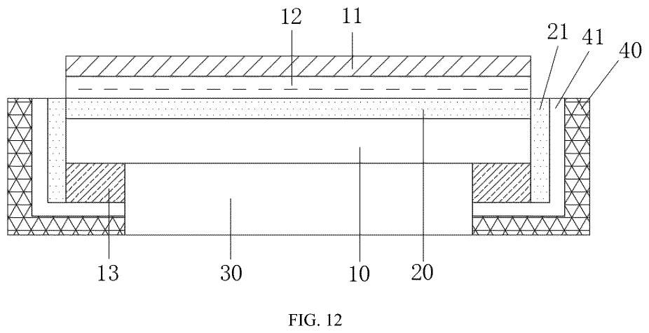

Based on the same creative concept, referring to FIG. 12, the present disclosure also provides a display module, including: a display panel 30 and any of the cover plates as described above disposed on a display side of the display panel 30.

Specifically, the cover plate includes the cover plate base 10, the anti-fingerprint film layer 11 and the electrostatic transfer layer 20. The cover plate base 10 is disposed on a side of the display panel 30, and the light shielding layer 13 is disposed between the cover plate base 10 and the display panel 30. The light shielding layer 13 is located in the edge region B of the cover plate. The anti-fingerprint film layer 11 is disposed on a side of the cover plate base 10 facing away from the display panel 30. The electrostatic transfer layer 20 is disposed between the cover plate base 10 and the anti-fingerprint film layer 11, or disposed between the cover plate base 10 and the light shielding layer 13.

Further, the display panel 30 may include an OLED display panel 30, a Micro-OLED display panel 30 or a quantum dot light emitting diodes (QLED) display panel 30. Exemplarily, when the display panel 30 is the OLED display panel 30, the display panel 30 may include an anode layer, an electron transport layer, a light emitting material layer, a hole transport layer, a hole injection layer, a cathode layer, and the like, which are stacked. The light emitting material layer may emit light to realize the display function of the display panel 30.

Further, as shown in FIG. 12, in a case that the cover plate includes the electrostatic conduction portion 21, the display module may further include a middle frame 40 and a middle frame adhesive layer 41. The middle frame 40 is disposed along a side face of the cover plate, and the middle frame 40 encloses a closed accommodating region enclosing the cover plate and the display panel 30. The middle frame 40 may include metal composites such as aluminum alloys, stainless steel, steel aluminum composites, and titanium alloys. The middle frame adhesive layer 41 is located between the middle frame 40 and the cover plate, and mainly serves to connect the middle frame 40 to the cover plate and the display panel 30. The material of the middle frame adhesive layer 41 may include a hot melt adhesive and the like.

The electrostatic conduction portion 21 is connected to the middle frame 40 through the middle frame adhesive layer 41, and the middle frame 40 is grounded. In this way, when the electrostatic charges are transferred to the electrostatic conduction portion 21, the electrostatic charges are then transferred to the middle frame 40 through the middle frame adhesive layer 41 and finally to a grounding point, so as to achieve the effect of electrostatic dissipation, thereby further avoiding damage to the anti-fingerprint film layer 11 and the cover plate base 10 caused by the accumulation of the electrostatic charges.

In order to ensure the transfer rate of the electrostatic charges between the middle frame adhesive layer 41 and the middle frame 40, the resistance values of the middle frame adhesive layer 41 and the middle frame 40 are required correspondingly. Specifically, the resistance value of the middle frame adhesive layer 41 is required to be less than or equal to the resistance value (10⁸Ω-10¹²Ω) of the electrostatic conduction portion 21 (namely, the electrostatic transfer layer 20). Also, the resistance value of the middle frame 40 is required to be less than or equal to the resistance value of the middle frame adhesive layer 41, so that the middle frame 40 and the middle frame adhesive layer 41 have a better conductive ability and anti-static ability, and the electrostatic charges may be better transferred and discharged from the middle frame adhesive layer 41 and the middle frame 40.

Based on the same creative concept, the present disclosure also provides a display device including any of the cover plates or display modules described herein.

Specifically, the display device may include an OLED display screen, a mobile device such as a mobile phone, a wearable device such as a watch, a VR device, and the like. Those skilled in the art would have been able to make a corresponding selection according to the specific use of the display device, and the description thereof will not be repeated herein.

References herein to “one embodiment,” “an embodiment,” or “one or more embodiments” mean that a particular feature, structure, or characteristic described in connection with the embodiments are included in at least one embodiment of the present disclosure. In addition, please note that wordings such as “in one embodiment” herein do not necessarily all refer to the same embodiment.

In the description provided herein, numerous specific details are set forth. However, it is understood that embodiments of the present disclosure may be practiced without these specific details. In some instances, common methods, structures and techniques have not been shown in detail in order not to obscure the understanding of this description.

In the claims, any reference signs placed between parentheses shall not be construed as limiting the claims. The word “comprising” does not exclude the presence of elements or steps not listed in the claims. The word “a” or “an” preceding an element does not exclude the presence of a plurality of such elements. The disclosure may be implemented by means of hardware including several distinct elements and a suitably programmed computer. In a unit claim enumerating several devices, several of these devices may be embodied by the same hardware item. The words such as “first”, “second”, and “third” as used do not indicate any order. These words may be interpreted as names.

Finally, it should be noted that the above embodiments are only used to illustrate the technical solution of the present disclosure, but not to limit it; although the present disclosure has been described in detail with reference to the foregoing embodiments, those skilled in the art should understand that any modifications may be made to the technical solutions described in the foregoing embodiments, or equivalent substitutions may be made to some of the technical features; however, these modifications or substitutions do not cause the essence of the corresponding technical solutions to deviate from the spirit and scope of the technical solutions of the embodiments of the present disclosure.

1. A cover plate, comprising:
a cover plate base and an anti-fingerprint film layer disposed on a side of the cover plate base; and
an electrostatic transfer layer disposed between the cover plate base and the anti-fingerprint film layer or disposed on a side of the cover plate base facing away from the anti-fingerprint film layer,
wherein the electrostatic transfer layer is configured to transfer static electricity generated by the cover plate.

2. The cover plate according to claim 1, further comprising:
a substrate layer doped with conductive particles;
wherein when the electrostatic transfer layer is disposed between the cover plate base and the anti-fingerprint film layer, the substrate layer is located between the electrostatic transfer layer and the anti-fingerprint film layer;
when the electrostatic transfer layer is disposed on the side of the cover plate base facing away from the anti-fingerprint film layer, the substrate layer is located between the cover plate base and the anti-fingerprint film layer.

3. The cover plate according to claim 1, wherein the cover plate comprises a central region and an edge region surrounding the central region, and the cover plate further comprises:
a light shielding layer located in the edge region;
wherein when the electrostatic transfer layer is disposed between the cover plate base and the anti-fingerprint film layer, the light shielding layer is located on a side of the cover plate base facing away from the electrostatic transfer layer;
when the electrostatic transfer layer is disposed on the side of the cover plate base facing away from the anti-fingerprint film layer, the light shielding layer is located on a side of the electrostatic transfer layer facing away from the cover plate base.

4. The cover plate according to claim 1, further comprising:
an electrostatic conduction portion connected to the electrostatic transfer layer and located on at least one side face of the cover plate base, the side face connecting a surface on a side of the cover plate base close to the anti-fingerprint film layer and a surface on the side of the cover plate base facing away from the anti-fingerprint film layer.

5. The cover plate according to claim 4, wherein the electrostatic conduction portion and the electrostatic transfer layer are made of a same material and have an integrated structure.

6. The cover plate according to claim 1, wherein a material of the electrostatic transfer layer comprises at least one of: ITO, AZO, ZnO, Al₂O₃, Nb₂O₅, NiO₂, TiO₂, SnO₂, In₂O₃, Ga₂O₃, MgZnO, GalnO, and InGaZnO.

7. The cover plate according to claim 1, wherein the electrostatic transfer layer has a transmittance greater than or equal to 98% for light with a wavelength of 550 nm.

8. The cover plate according to claim 1, wherein the electrostatic transfer layer has a thickness greater than or equal to 1 nm, and less than or equal to 15 nm.

9. The cover plate according to claim 1, wherein a resistance value of a surface of the electrostatic transfer layer close to the anti-fingerprint film layer is greater than or equal to 10⁸Ω and less than or equal to 10¹²Ω;

10. The cover plate according to claim 1, wherein the anti-fingerprint film layer comprises at least one of: fluorine chains, non-fluorine groups and terminal groups.

11. The cover plate according to claim 10, wherein a relative molecular weight of the fluorine chains is greater than or equal to 1000, and less than or equal to 4500.

12. The cover plate according to claim 10, wherein a number of terminal groups is greater than or equal to 2.

13. The cover plate according to claim 1, wherein the cover plate base comprises a plurality of sub-film layers stacked;
wherein the plurality of sub-film layers are all made of a flexible material.

14. A display module, comprising:
a display panel; and
a cover plate according to disposed on a display side of the display panel, wherein cover plate comprises: a cover plate base and an anti-fingerprint film layer disposed on a side of the cover plate base; and an electrostatic transfer layer disposed between the cover plate base and the anti-fingerprint film layer or disposed on a side of the cover plate base facing away from the anti-fingerprint film layer, wherein the electrostatic transfer layer is configured to transfer static electricity generated by the cover plate;
wherein the anti-fingerprint film layer is disposed on a side of the cover plate base facing away from the display panel.

15. The display module according to claim 14, wherein the cover plate comprises an electrostatic conduction portion connected to the electrostatic transfer layer and located on at least one side face of the cover plate base, the side face connecting a surface on a side of the cover plate base close to the anti-fingerprint film layer and a surface on the side of the cover plate base facing away from the anti-fingerprint film layer, the display module further comprises:
a middle frame disposed along a side face of the cover plate and enclosing the cover plate and the display panel; and
a middle frame adhesive layer located between the middle frame and the side face of the cover plate;
wherein the electrostatic conduction portion is connected to the middle frame through the middle frame adhesive layer.

16. The display module according to claim 15, wherein a resistivity of the middle frame adhesive layer is less than or equal to the resistivity of the electrostatic conduction portion, and the resistivity of the middle frame is less than or equal to the resistivity of the middle frame adhesive layer.

17. A display device, comprising the display module according to claim 16.

18. The cover plate according to claim 1, wherein a surface roughness on a side of the electrostatic transfer layer close to the anti-fingerprint film layer is less than 0.5 nm.

19. The cover plate according to claim 9, wherein a surface roughness on a side of the electrostatic transfer layer close to the anti-fingerprint film layer is less than 0.5 nm.
